(19) United States
(12) Patent Application Publication
(10) Pub. No.: US 2021/0336236 A1
(43) Pub. Date: Oct. 28, 2021

(54) DISPLAY PANEL AND MANUFACTURING METHOD THEREOF

(71) Applicant: SHENZHEN CHINA STAR OPTOELECTRONICS SEMICONDUCTOR DISPLAY TECHNOLOGY CO., LTD., Shenzhen (CN)

(72) Inventors: Xianglong LI, Shenzhen (CN); Iguchi SHINSUKE, Shenzhen (CN)

(73) Assignee: SHENZHEN CHINA STAR OPTOELECTRONICS SEMICONDUCTOR DISPLAY TECHNOLOGY CO., LTD., Shenzhen (CN)

(21) Appl. No.: 16/617,511

(22) PCT Filed: Sep. 6, 2019
(86) PCT No.: PCT/CN2019/104682

§ 371 Date: Nov. 27, 2019

(30) Foreign Application Priority Data
May 7, 2019 (CN) 201910374638.4

(51) Int. Cl. H01L 51/56; H01L 51/52

(52) U.S. Cl. CPC H01L 51/56; H01L 51/5265; H01L 51/5271; H01L 51/5237

(57) ABSTRACT

A display panel and a manufacturing method thereof are provided. The display panel comprises a substrate, a light-emitting device layer, and an encapsulation layer. The light-emitting device layer comprises an anode layer, a light-emitting layer, a cathode layer, and a light transmission layer between the cathode layer and the substrate.

### FIELD OF INVENTION

The present disclosure relates to the field of display technologies, and more particularly to a display panel and a manufacturing method thereof.

### BACKGROUND OF INVENTION

In flat panel display technologies, organic light-emitting diode (OLED) displays have many advantages, such as light weight, thinness, active illumination, fast response times, large viewing angles, wide color gamut, high brightness, and low power consumption, allowing them to gradually become the third generation display technology after liquid crystal displays.

In the production of current OLED devices, a light-emitting layer is usually disposed between a total reflective structure and a semi-reflective structure to form microcavity effect, thereby improving luminous efficiency of devices. Because the microcavity effect needs to be formed in a thicker device, the OLED light-emitting layer is thicker. Due to the high price of OLED light-emitting materials, the cost of OLED display panels is relatively high. Therefore, it is necessary to provide a display panel to reduce the production cost of the product.

### SUMMARY OF INVENTION

An object of the present disclosure is to provide a display panel and a manufacturing method thereof to reduce the production cost of current display panels.

To achieve the above object, the present disclosure provides following solutions:

an embodiment of the present disclosure provides a manufacturing method of a display panel. The method comprises:

S10: providing a substrate, and forming an anode layer on the substrate;

S20: forming a light-emitting layer on the anode layer;

S30: forming a cathode layer on the light-emitting layer;

S40: forming an encapsulation layer on the cathode layer;

wherein the manufacturing method further comprises:

forming a light transmission layer between the substrate and the cathode layer.

In an embodiment of the present disclosure, the light transmission layer is disposed between the light-emitting layer and the anode layer.

In an embodiment of the present disclosure, the light transmission layer is disposed between the light-emitting layer and the cathode layer.

In an embodiment of the present disclosure, the light transmission layer is disposed between the substrate and the anode layer.

In an embodiment of the present disclosure, the manufacturing method of a display panel further comprises:

forming a reflective layer on a surface of the substrate; wherein the reflective layer is made of a total reflection material.

In an embodiment of the present disclosure, the light transmission layer is disposed between the light-emitting layer and the anode layer.

In an embodiment of the present disclosure, the light transmission layer is disposed between the light-emitting layer and the cathode layer.

In an embodiment of the present disclosure, the light transmission layer is disposed between the reflective layer and the anode layer.

In an embodiment of the present disclosure, the light transmission layer comprises one or more combinations selected from the group consisting of an inorganic oxide, an inorganic nitride, or an organic polymer.

An embodiment of the present disclosure further provides a display panel. The display panel comprises: a substrate, a light-emitting device layer disposed on the substrate, and an encapsulation layer disposed on the light-emitting device layer; wherein the light-emitting device layer comprises an anode layer, a light-emitting layer disposed on the anode layer, a cathode layer disposed on the light-emitting layer, and a light transmission layer disposed between the cathode layer and the substrate.

In an embodiment of the present disclosure, the light transmission layer is disposed between the light-emitting layer and the anode layer.

In an embodiment of the present disclosure, the light transmission layer is disposed between the light-emitting layer and the cathode layer.

In an embodiment of the present disclosure, the light transmission layer is disposed between the substrate and the anode layer.

In an embodiment of the present disclosure, the display panel further comprises a reflective layer disposed on a surface of the substrate, wherein the reflective layer is made of a total reflection material.

In an embodiment of the present disclosure, the light transmission layer is disposed between the light-emitting layer and the anode layer.

In an embodiment of the present disclosure, the light transmission layer is disposed between the light-emitting layer and the cathode layer.

In an embodiment of the present disclosure, the light transmission layer is disposed between the reflective layer and the anode layer.

In an embodiment of the present disclosure, the light transmission layer comprises one or more combinations selected from the group consisting of an inorganic oxide, an inorganic nitride, or an organic polymer.

The beneficial effect is: the present disclosure provides a display panel and a manufacturing method thereof. The display panel comprises a substrate, a light-emitting device layer, and an encapsulation layer. The light-emitting device layer comprises an anode layer, a light-emitting layer, a cathode layer, and a light transmission layer between the cathode layer and the substrate. It reduces the thickness of the light-emitting layer by disposing a light transmission layer in the light-emitting device layer to substitute partial light-emitting layer, thereby reducing the amount of light-emitting layer materials and the production cost.

### DESCRIPTION OF DRAWINGS

The accompanying figures to be used in the description of embodiments of the present disclosure or prior art will be described in brief to more clearly illustrate the technical solutions of the embodiments or the prior art. The accompanying figures described below are only part of the embodiments of the present disclosure, from which those skilled in the art can derive further figures without making any inventive efforts.

FIG. 1 is a flowchart of a manufacturing method of a display panel according to an embodiment of the present disclosure.

FIG. 2 is a schematic structural diagram of a current display panel.

FIG. 3 is a first schematic structural diagram of a display panel according to an embodiment of the present disclosure.

FIG. 4 is a second schematic structural diagram of a display panel according to an embodiment of the present disclosure.

FIG. 5 is a third schematic structural diagram of a display panel according to an embodiment of the present disclosure.

FIG. 6 is a fourth schematic structural diagram of a display panel according to an embodiment of the present disclosure.

FIG. 7 is a fifth schematic structural diagram of a display panel according to an embodiment of the present disclosure.

FIG. 8 is a sixth schematic structural diagram of a display panel according to an embodiment of the present disclosure.

FIG. 9 is a seventh schematic structural diagram of a display panel according to an embodiment of the present disclosure.

FIG. 10 is an eighth schematic structural diagram of a display panel according to an embodiment of the present disclosure.

### DETAILED DESCRIPTION OF PREFERRED EMBODIMENTS

The embodiments of the present disclosure are described in detail hereinafter. Examples of the described embodiments are given in the accompanying drawings, wherein the identical or similar reference numerals constantly denote the identical or similar elements or elements having the identical or similar functions. In the description of the present disclosure, it should be understood that terms such as “upper”, “lower”, “front”, “rear”, “left”, “right”, “inside”, “outside”, “side”, as well as derivative thereof should be construed to refer to the orientation as described or as shown in the drawings under discussion. These relative terms are for convenience of description, do not require that the present disclosure be constructed or operated in a particular orientation, and shall not be construed as causing limitations to the present disclosure.

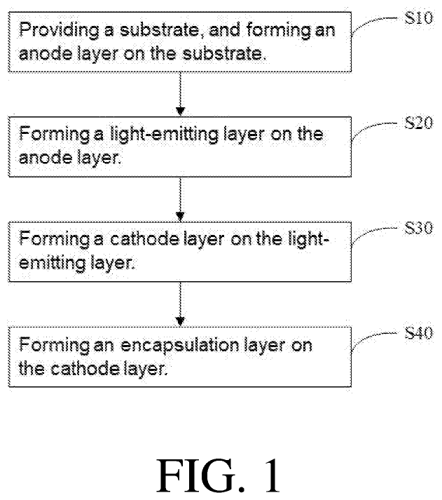

Referring to FIG. 1, FIG. 1 is a flowchart of a manufacturing method of a display panel according to an embodiment of the present disclosure.

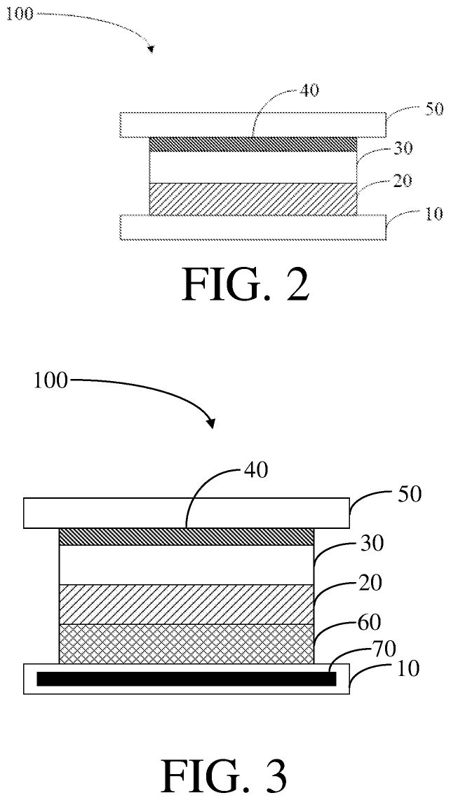

Referring to FIG. 2, FIG. 2 is a schematic structural diagram of a current display panel.

A manufacturing method of a display panel 100 comprises:

S10: providing a substrate 10, and forming an anode layer 20 on the substrate 10.

Referring to FIG. 2, the substrate 10 can be an array substrate.

The substrate 10 comprises a substrate and a thin film transistor layer disposed on the substrate.

The substrate can be a glass substrate, a quartz substrate, or a resin substrate. When the substrate is a flexible substrate, the flexible substrate can be made of polyimide (PI).

The thin film transistor layer comprises a plurality of thin film transistor units. The thin film transistor unit can be an etch stopper type, a back channel etch type, or a top gate thin film transistor type. The embodiment is not specifically limited thereto.

An embodiment of the present disclosure takes the top gate thin film transistor type as an example for description.

For example, the thin film transistor unit comprises a light shielding layer, a buffer layer, an active layer, a gate insulating layer, a gate electrode, an interlayer insulating layer, a source and drain electrode, a passivation layer, and a planar layer.

The anode layer 20 is formed on the planar layer.

A plurality of anodes is formed by patterning on the anode layer 20.

The anode layer 20 is primarily used to provide holes for absorbing electrons.

S20: forming a light-emitting layer 30 on the anode layer 20.

Referring to FIG. 2, the light-emitting layer 30 is divided into a plurality of light-emitting units by a pixel definition layer (not shown). The light-emitting units are in one-to-one correspondence with the anodes.

The light-emitting layer 30 comprises an organic light-emitting material. The material is an organic semiconductor which has a particular energy band structure that can absorb electrons migrating from the anode and then emit photons with a predetermined wavelength. These photons enter our eyes and form the colors we see.

S30: forming a cathode layer 40 on the light-emitting layer 30.

Referring to FIG. 2, the cathode layer covers the light-emitting layer 30. The cathode layer is used to provide electrons absorbed by the holes.

S40: forming an encapsulation layer 50 on the cathode layer.

Referring to FIG. 2, the encapsulation layer 50 can be a thin film encapsulation layer which is mainly used as a water and oxygen barrier that prevents external water vapor from eroding the organic light-emitting layer 30. The encapsulation layer 50 can be formed by at least one organic layer and at least one inorganic layer laminated alternately. The organic layer is usually disposed in the middle of the encapsulation layer 50, and the inorganic layers are disposed on both sides of the encapsulation layer 50, wrapping the organic layer in the middle.

In an embodiment of the present disclosure, the manufacturing method of the display panel 100 further comprises:

forming a light transmission layer 60 between the substrate 10 and the cathode layer.

When the display panel 100 is a top emitting OLED device, the anode layer 20 can be a transparent electrode or a non-transparent electrode.

When the anode layer 20 is a transparent electrode, a reflective film layer 70 is disposed between the anode layer 20 and the substrate 10, or disposed in the substrate 10, which reflects light produced by the light-emitting layer 30 from the top.

Referring to FIG. 3, FIG. 3 is a first schematic structural diagram of the display panel 100 according to an embodiment of the present disclosure.

Referring to FIG. 3, the light transmission layer 60 is disposed between the anode layer 20 and the substrate 10. The light transmission layer 60 is manufactured before manufacturing the anode layer 20.

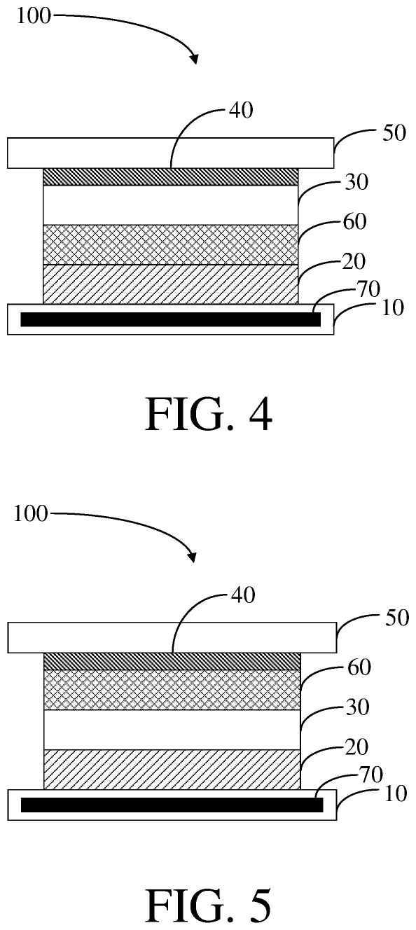

Referring to FIG. 4, FIG. 4 is a second schematic structural diagram of the display panel according to an embodiment of the present disclosure.

Referring to FIG. 4, the light transmission layer 60 is disposed between the anode layer 20 and the light-emitting layer 30. The light transmission layer 60 is manufactured before manufacturing the light-emitting layer 30.

Referring to FIG. 5, FIG. 5 is a third schematic structural diagram of the display panel according to an embodiment of the present disclosure.

Referring to FIG. 5, the light transmission layer 60 is disposed between the cathode layer and the light-emitting layer 30. The light transmission layer 60 is manufactured before manufacturing the cathode layer.

From FIG. 3 to FIG. 5, in order to achieve microcavity effect in the light emitting device, it is necessary to dispose the reflective film layer 70 on one side of the light emitting device. The reflective film layer 70 in the above embodiments can be disposed in the substrate 10. That is, a film layer structure in the substrate 10 is provided with the reflective film layer 70. For example, the reflective film layer 70 is disposed in a thicker planar layer.

From FIG. 3 to FIG. 5, a total reflection of the reflective film layer 70 and a semi-reflection of the cathode layer form microcavity effect. Addition of the light transmission layer 60 substitutes a partial original light-emitting layer 30, and reduces an amount of the light-emitting layer 30 materials on the basis of achieving the same luminous effect, thereby reducing production cost.

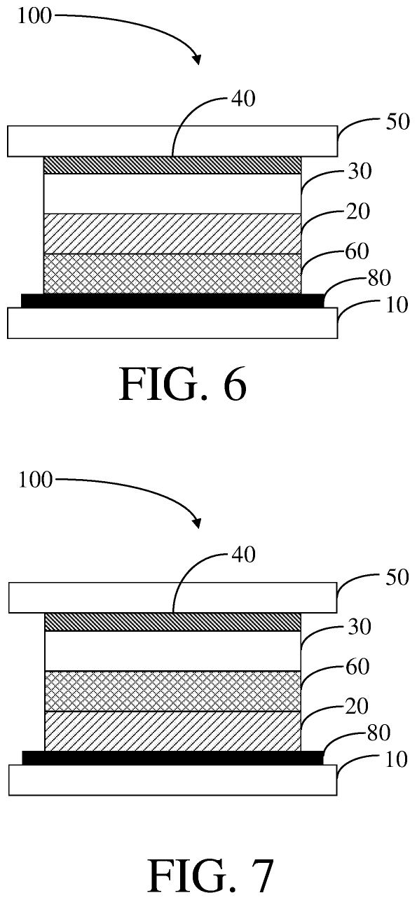

Referring to FIG. 6, FIG. 6 is a fourth schematic structural diagram of the display panel according to an embodiment of the present disclosure.

Referring to FIG. 7, FIG. 7 is a fifth schematic structural diagram of the display panel according to an embodiment of the present disclosure.

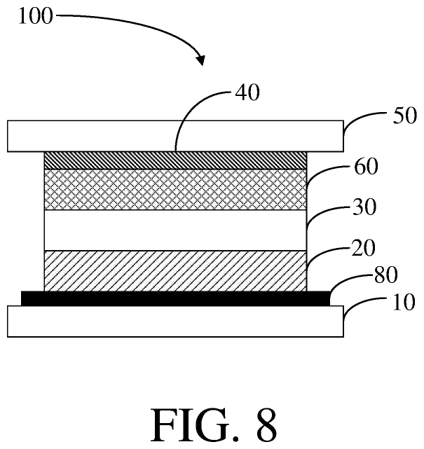

Referring to FIG. 8, FIG. 8 is a sixth schematic structural diagram of the display panel according to an embodiment of the present disclosure.

Referring to FIG. 6 and FIG. 7, the manufacturing method of the display panel 100 further comprises:

Forming a reflective layer 80 on a surface of the substrate 10.

The reflective layer 80 is made of a total reflection material, and can be used as a reflective electrode.

Referring to FIG. 6, the light transmission layer 60 is disposed between the anode layer 20 and the reflective layer 80. The light transmission layer 60 is manufactured before manufacturing the anode layer 20.

Referring to FIG. 7, the light transmission layer 60 is disposed between the anode layer 20 and the light-emitting layer 30. The light transmission layer 60 is manufactured before manufacturing the light-emitting layer 30.

Referring to FIG. 8, the light transmission layer 60 is disposed between the cathode layer and the light-emitting layer 30. The light transmission layer 60 is manufactured before manufacturing the cathode layer.

From FIG. 6 to FIG. 8, a total reflection of the reflective layer 80 and a semi-reflection of the cathode layer form microcavity effect. Addition of the light transmission layer 60 substitutes a partial original light-emitting layer 30, and reduces the amount of the light-emitting layer 30 materials on the basis of achieving the same luminous effect, thereby reducing production cost.

From FIG. 6 to FIG. 8, the anode layer 20 can be a transparent electrode. The cathode layer can be a translucent electrode.

Partial light emitted from the light-emitting layer 30 completely passes through the anode layer 20, and is totally reflected by the reflective layer 80 or the reflective film layer 70 to the cathode layer.

From FIG. 3 to FIG. 8, the transparent anode layer 20 material can be at least one of indium tin oxide (ITO), indium zinc oxide (IZO), zinc oxide (ZnO), indium oxide (In₂O₃), indium gallium oxide (IGO), or zinc aluminum oxide (AZO).

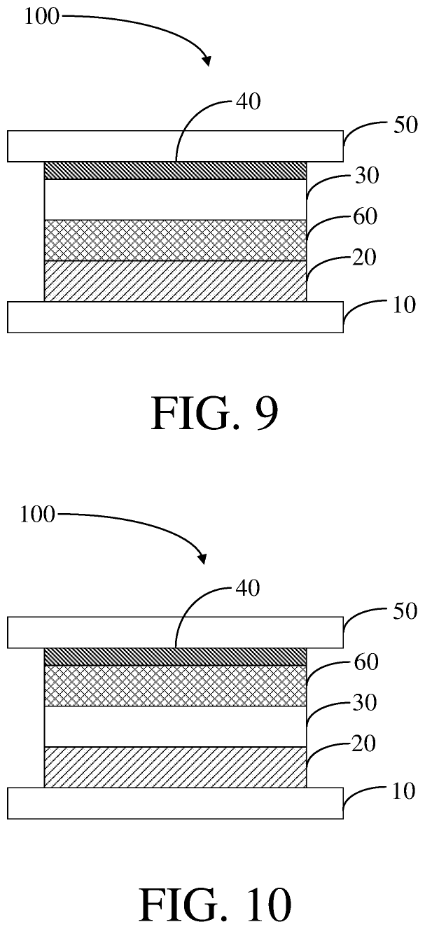

Referring to FIG. 9, FIG. 9 is a seventh schematic structural diagram of the display panel according to an embodiment of the present disclosure.

Referring to FIG. 9, the light transmission layer 60 is disposed between the anode layer 20 and the light-emitting layer 30. The light transmission layer 60 is manufactured before manufacturing the light-emitting layer 30.

Referring to FIG. 10, FIG. 10 is an eighth schematic structural diagram of the display panel according to an embodiment of the present disclosure.

Referring to FIG. 10, the light transmission layer 60 is disposed between the cathode layer and the light-emitting layer 30. The light transmission layer 60 is manufactured before manufacturing the cathode layer.

In FIG. 9 and FIG. 10, the anode layer 20 can be a non-transparent electrode. The anode layer 20 is made of a total reflection material. The cathode layer can be a translucent electrode, and the cathode layer is made of a semi-reflective material.

In FIG. 9 and FIG. 10, a total reflection of the anode layer 20 and a semi-reflection of the cathode layer form microcavity effect. Addition of the light transmission layer 60 substitutes a partial original light-emitting layer 30, and reduces the amount of the light-emitting layer 30 materials on the basis of achieving the same luminous effect, thereby reducing production cost.

From FIG. 3 to FIG. 10, the light transmission layer 60 is made of a high transmittance material. The light transmission layer 60 comprises one or more combinations selected from the group consisting of an inorganic oxide, an inorganic nitride, and an organic polymer.

For example, the inorganic oxide can be silicon oxide (SiOx), the inorganic nitride can be silicon nitride (SiNx), and the organic polymer can be polymethylmethacrylate (PMMA) or polypropylene (PP). Additives, such as initiators or terminators, can be added to the organic polymer.

In the above embodiments, when the light transmission layer 60 is disposed between the anode layer 20 and the light-emitting layer 30, the light transmission layer 60 is manufactured by a material with high conductivity and high work function to ensure the luminous effect of the light-emitting layer 30. When the light transmission layer 60 is disposed between the cathode layer and the light-emitting layer 30, the light transmission layer 60 is manufactured by a material with high conductivity and low work function to ensure the luminous effect of the light-emitting layer 30.

Similarly, when the display panel 100 is a bottom emitting OLED device, the cathode layer can be used as a total reflective layer 80, and the anode layer 20, the reflective layer 80, or the reflective film layer 70 can be used as a semi-reflective layer 80, and microcavity effect can be formed similarly. The specific manufacturing method is the same as or similar to that of the top emitting device, and is not iterated herein for the sake of conciseness.

The embodiment of the present disclosure reduces the thickness of the light-emitting layer 30 by disposing the light transmission layer 60 in the light-emitting device layer to substitute partial light-emitting layer 30, thereby reducing the amount of the light-emitting layer 30 materials and production cost.

Referring to FIG. 2, an embodiment of the present disclosure further provides the display panel 100. The display panel 100 comprises the substrate 10, the light-emitting device layer disposed on the substrate 10, and an encapsulation layer 50 disposed on the light-emitting device layer.

The substrate 10 comprises a substrate and a thin film transistor layer disposed on the substrate.

The substrate can be a glass substrate, a quartz substrate, or a resin substrate. When the substrate is a flexible substrate, the flexible substrate can be made of polyimide (PI).

The thin film transistor layer comprises a plurality of thin film transistor units. The thin film transistor unit can be an etch stopper type, a back channel etch type, or a top gate thin film transistor type. The embodiment is not specifically limited thereto.

An embodiment of the present disclosure takes the top gate thin film transistor type as an example for description.

For example, the thin film transistor unit comprises a light shielding layer, a buffer layer, an active layer, a gate insulating layer, a gate electrode, an interlayer insulating layer, a source and drain electrode, a passivation layer, and a planar layer.

The light-emitting device layer comprises the anode layer 20, the light-emitting layer 30 disposed on the anode layer 20, and the cathode layer disposed on the light-emitting layer 30.

The anode layer 20 is formed on the planar layer.

A plurality of anodes is formed by patterning on the anode layer 20.

The anode layer 20 is primarily used to provide holes for absorbing electrons.

The light-emitting layer 30 is divided into a plurality of light-emitting units by a pixel definition layer (not shown). The light-emitting units are in one-to-one correspondence with the anodes.

The light-emitting layer 30 comprises an organic light-emitting material. The material is an organic semiconductor which has a particular energy band structure that can absorb electrons migrating from the anode and then emit photons with a predetermined wavelength. These photons enter our eyes and form the colors we see.

The cathode layer covers the light-emitting layer 30. The cathode layer is used to provide electrons absorbed by the holes.

The encapsulation layer 50 can be a thin film encapsulation layer 50 which is mainly used as a water and oxygen barrier that prevents external water vapor from eroding the organic light-emitting layer 30. The encapsulation layer 50 can be formed by at least one organic layer and at least one inorganic layer laminated alternately. The organic layer is usually disposed in the middle of the encapsulation layer 50, and the inorganic layers are disposed on both sides of the encapsulation layer 50, wrapping the organic layer in the middle.

Referring to FIG. 3, the display panel 100 further comprises the light transmission layer 60 disposed between the cathode layer and the substrate 10.

When the display panel 100 is a top emitting OLED device, the anode layer 20 can be a transparent electrode or a translucent electrode.

When the anode layer 20 is a transparent electrode, the reflective film layer 70 is disposed between the anode layer 20 and the substrate 10, or disposed in the substrate 10, which reflects light produced by the light-emitting layer 30 from the top.

Referring to FIG. 3, FIG. 3 is a first schematic structural diagram of the display panel according to an embodiment of the present disclosure.

Referring to FIG. 3, the light transmission layer 60 is disposed between the anode layer 20 and the substrate 10. The light transmission layer 60 is manufactured before manufacturing the anode layer 20.

Referring to FIG. 4, FIG. 4 is a second schematic structural diagram of the display panel according to an embodiment of the present disclosure.

Referring to FIG. 4, the light transmission layer 60 is disposed between the anode layer 20 and the light-emitting layer 30. The light transmission layer 60 is manufactured before manufacturing the light-emitting layer 30.

Referring to FIG. 5, FIG. 5 is a third schematic structural diagram of the display panel according to an embodiment of the present disclosure.

Referring to FIG. 5, the light transmission layer 60 is disposed between the cathode layer and the light-emitting layer 30. The light transmission layer 60 is manufactured before manufacturing the cathode layer.

From FIG. 3 to FIG. 5, in order to achieve microcavity effect in the light-emitting device, it is necessary to dispose the reflective film layer 70 on one side of the light emitting device. The reflective film layer 70 in the above embodiments can be disposed in the substrate 10. That is, a film layer structure in the substrate 10 is provided with the reflective film layer 70. For example, the reflective film layer 70 is disposed in a thicker planar layer.

From FIG. 3 to FIG. 5, the total reflection of the reflective film layer 70 and the semi-reflection of the cathode layer form microcavity effect. Addition of the light transmission layer 60 substitutes a partial original light-emitting layer 30, and reduces the amount of the light-emitting layer 30 materials on the basis of achieving the same luminous effect, thereby reducing production cost.

Referring to FIG. 6, FIG. 6 is a fourth schematic structural diagram of the display panel according to an embodiment of the present disclosure.

Referring to FIG. 7, FIG. 7 is a fifth schematic structural diagram of the display panel according to an embodiment of the present disclosure.

Referring to FIG. 8, FIG. 8 is a sixth schematic structural diagram of the display panel according to an embodiment of the present disclosure.

Referring to FIG. 6 and FIG. 7, the manufacturing method of the display panel 100 further comprises:

Forming the reflective layer 80 on a surface of the substrate 10.

The reflective layer 80 is made of a total reflection material, and can be used as a reflective electrode.

Referring to FIG. 6, the light transmission layer 60 is disposed between the anode layer 20 and the reflective layer 80. The light transmission layer 60 is manufactured before manufacturing the anode layer 20.

Referring to FIG. 7, the light transmission layer 60 is disposed between the anode layer 20 and the light-emitting layer 30. The light transmission layer 60 is manufactured before manufacturing the light-emitting layer 30.

Referring to FIG. 8, the light transmission layer 60 is disposed between the cathode layer and the light-emitting layer 30. The light transmission layer 60 is manufactured before manufacturing the cathode layer.

From FIG. 6 to FIG. 8, the total reflection of the reflective layer 80 and the semi-reflection of the cathode layer form microcavity effect. Addition of the light transmission layer 60 substitutes a partial original light-emitting layer 30, and reduces the amount of the light-emitting layer 30 materials on the basis of achieving the same luminous effect, thereby reducing production cost.

From FIG. 6 to FIG. 8, the anode layer 20 can be a transparent electrode. The cathode layer can be a translucent electrode.

Partial light emitted from the light-emitting layer 30 completely passes through the anode layer 20, and is totally reflected by the reflective layer 80 or the reflective film layer 70 to the cathode layer.

From FIG. 3 to FIG. 8, the transparent anode layer 20 material can be at least one of indium tin oxide (ITO), indium zinc oxide (IZO), zinc oxide (ZnO), indium oxide (In₂O₃), indium gallium oxide (IGO), or zinc aluminum oxide (AZO).

Referring to FIG. 9, FIG. 9 is a seventh schematic structural diagram of the display panel according to an embodiment of the present disclosure.

Referring to FIG. 9, the light transmission layer 60 is disposed between the anode layer 20 and the light-emitting layer 30. The light transmission layer 60 is manufactured before manufacturing the light-emitting layer 30.

Referring to FIG. 10, FIG. 10 is an eighth schematic structural diagram of the display panel according to an embodiment of the present disclosure.

Referring to FIG. 10, the light transmission layer 60 is disposed between the cathode layer and the light-emitting layer 30. The light transmission layer 60 is manufactured before manufacturing the cathode layer.

In FIG. 9 and FIG. 10, the anode layer 20 can be a non-transparent electrode. The anode layer 20 is made of a total reflection material. The cathode layer can be a translucent electrode, and the cathode layer is made of a semi-reflective material.

In FIG. 9 and FIG. 10, the total reflection of the anode layer 20 and the semi-reflection of the cathode layer form microcavity effect. Addition of the light transmission layer 60 substitutes a partial original light-emitting layer 30, and reduces the amount of the light-emitting layer 30 materials on the basis of achieving the same luminous effect, thereby reducing production cost.

From FIG. 3 to FIG. 10, the light transmission layer 60 is made of a high transmittance material. The light transmission layer 60 comprises one or more combinations selected from the group consisting of an inorganic oxide, an inorganic nitride, or an organic polymer.

For example, the inorganic oxide can be silicon oxide (SiOx), the inorganic nitride can be silicon nitride (SiNx), and the organic polymer can be polymethylmethacrylate (PMMA) or polypropylene (PP). Additives, such as initiators or terminators, can be added in the organic polymer.

In the above embodiments, when the light transmission layer 60 is disposed between the anode layer 20 and the light-emitting layer 30, the light transmission layer 60 is manufactured by a material with high conductivity and high work function to ensure the luminous effect of the light-emitting layer 30. When the light transmission layer 60 is disposed between the cathode layer and the light-emitting layer 30, the light transmission layer 60 is manufactured by a material with high conductivity and low work function to ensure the luminous effect of the light-emitting layer 30.

Similarly, when the display panel 100 is a bottom emitting OLED device, the cathode layer is as a total reflective layer 80, the anode layer 20, the reflective layer 80, or the reflective film layer 70 can be a semi-reflective layer 80, and microcavity effect can be formed similarly. The specific manufacturing method is the same as or similar to that of the top emitting device, and is not iterated herein for the sake of conciseness.

The embodiment of the present disclosure reduces the thickness of the light-emitting layer 30 by disposing the light transmission layer 60 in the light-emitting device layer to substitute partial light-emitting layer, thereby reducing the amount of light-emitting layer materials and production cost.

The present disclosure provides a display panel and a manufacturing method thereof. The display panel comprises a substrate, a light-emitting device layer, and an encapsulation layer. The light-emitting device layer comprises an anode layer, a light-emitting layer, a cathode layer, and a light transmission layer disposed between the cathode layer and the substrate. The present disclosure reduces the thickness of the light-emitting layer by disposing the light transmission layer in the light-emitting device layer to substitute partial light-emitting layer, thereby reducing the amount of light-emitting layer materials and production cost.

The present disclosure has been described with a preferred embodiment thereof. The preferred embodiment is not intended to limit the present disclosure, and it is understood that many changes and modifications to the described embodiment can be carried out without departing from the scope and the spirit of the disclosure that is intended to be limited only by the appended claims.

What is claimed is:

1. A manufacturing method of a display panel, comprising:
S10: providing a substrate, and forming an anode layer on the substrate;
S20: forming a light-emitting layer on the anode layer;
S30: forming a cathode layer on the light-emitting layer; and
S40: forming an encapsulation layer on the cathode layer;
wherein the manufacturing method further comprises:
forming a light transmission layer between the substrate and the cathode layer.

2. The manufacturing method according to claim 1, wherein
the light transmission layer is disposed between the light-emitting layer and the anode layer.

3. The manufacturing method according to claim 1, wherein
the light transmission layer is disposed between the light-emitting layer and the cathode layer.

4. The manufacturing method according to claim 1, wherein
the light transmission layer is disposed between the substrate and the anode layer.

5. The manufacturing method according to claim 1, further comprising:
forming a reflective layer on a surface of the substrate; wherein the reflective layer is made of a total reflection material.

6. The manufacturing method according to claim 5, wherein the light transmission layer is disposed between the light-emitting layer and the anode layer.

7. The manufacturing method according to claim 5, wherein the light transmission layer is disposed between the light-emitting layer and the cathode layer.

8. The manufacturing method according to claim 5, wherein the light transmission layer is disposed between the reflective layer and the anode layer.

9. The manufacturing method according to claim 8, wherein the light transmission layer comprises one or more combinations selected from the group consisting of an inorganic oxide, an inorganic nitride, or an organic polymer.

10. A display panel, comprising: a substrate, a light-emitting device layer disposed on the substrate, and an encapsulation layer disposed on the light-emitting device layer; wherein the light-emitting device layer comprises an anode layer, a light-emitting layer disposed on the anode layer, a cathode layer disposed on the light-emitting layer, and a light transmission layer disposed between the cathode layer and the substrate.

11. The display panel according to claim 10, wherein
the light transmission layer is disposed between the light-emitting layer and the anode layer.

12. The display panel according to claim 10, wherein
the light transmission layer is disposed between the light-emitting layer and the cathode layer.

13. The display panel according to claim 10, wherein
the light transmission layer is disposed between the substrate and the anode layer.

14. The display panel according to claim 10, further comprising a reflective layer disposed on a surface of the substrate; wherein the reflective layer is made of a total reflection material.

15. The display panel according to claim 14, wherein
the light transmission layer is disposed between the light-emitting layer and the anode layer.

16. The display panel according to claim 14, wherein
the light transmission layer is disposed between the light-emitting layer and the cathode layer.

17. The display panel according to claim 14, wherein
the light transmission layer is disposed between the reflective layer and the anode layer.

18. The display panel according to claim 10, wherein the light transmission layer comprises one or more combinations selected from the group consisting of an inorganic oxide, an inorganic nitride, or an organic polymer.
